(19) United States
(12) Patent Application Publication
(10) Pub. No.: US 2005/0064688 A1
(43) Pub. Date: Mar. 24, 2005

(54) Methods for fabricating semiconductor devices

(76) Inventor: Joon-Bum Shim, Seongnam-city (KR)

Correspondence Address: GROSSMAN & FLIGHT LLC;Suite 4220, 20 North Wacker Drive, Chicago, IL, 60606-6357, US

(21) Appl. No.: 10/946,155

(22) Filed: Sep. 21, 2004

(30) Foreign Application Priority Data
Sep. 24, 2003 (KR) 10-2003-0066374

(51) Int. Cl. G03C 1/492; H01L 21/3205; H01L 21/461; H01L 21/4763

(52) U.S. Cl. 438/585; 438/689; 438/725

(57) ABSTRACT

Methods for fabricating semiconductor devices are disclosed. A disclosed method for fabricating a semiconductor device comprises: forming a film on a semiconductor substrate; forming a photoresist pattern on the film; etching the photoresist pattern by chemical dry etching (CDE) to reduce a width of the photoresist pattern; and etching an exposed portion of the film using the photoresist pattern as a mask.

### FIELD OF THE DISCLOSURE

The present disclosure relates generally to semiconductor fabrication and, more particularly, to methods for fabricating semiconductor devices.

### BACKGROUND

With the increasing miniaturization and increasing speed of semiconductor devices, the question of how to implement a device with much narrower linewidth has become a significant issue. In the photolithography process, photosensitive film is exposed to light rays of short wavelength in order to achieve much narrower linewidth. A Krypton Fluoride (KrF) laser is often used for this purpose. However, the KrF laser has a wavelength of 248 nm and is, thus, limited to achieving a 0.15 μm linewidth. In order to achieve a linewidth narrower than 0.13 μm, it has been proposed to use an Argon Fluorine (ArF) laser source having a wavelength of 193 μm. However, exchanging the light source used in the exposure process is too expensive. Therefore, it is desirable to develop a technique for fabricating a device having narrower linewidth without replacing the typical light source with a new light source.

Currently the photolithography technique employing a Krf laser is used for mass production. However, as mentioned above, with the prior art techniques, the KrF light source is not able to fabricate a device having a linewidth narrower than 0.13 μm. Accordingly, it would be desirable to achieve a fine linewidth (e.g., narrower than 0.13 μm) using a conventional KrF light source without additional equipment such as a new light source (e.g., without an ArF laser).

In a photolithography process using a conventional KrF laser, a photosensitive pattern is formed by sequentially: (a) depositing an anti-reflective coating (ARC) made of organic material for avoiding diffused reflection of the light on the film to be etched, (b) depositing the photosensitive film on the anti-reflective coating, and (c) irradiating the film with the KrF laser through a mask film, (called a reticle), located on the photosensitive film. After the film is exposed and etched in this manner, the photosensitive pattern is removed.

As described above, the critical dimension (CD) of the photosensitive pattern in the photolithography process using the KrF laser is 0.15 μm. It is impossible to achieve a linewidth narrower than 0.15 μm in the prior art processes employing a KrF laser.

Photosensitive film tends to be reflowed and contracted when heated to a high temperature in, for example, ashing equipment. A method for reducing the width of the photoresist pattern using this characteristic has been proposed. The proposed method first forms the photoresist pattern with a linewidth of 0.15 μm (critical dimension) using the conventional KrF laser process described above. It then contracts the photoresist pattern by heating the film in ashing equipment to form a photoresist pattern having a much narrower linewidth.

However, since the contractibility of the photoresist pattern is unequal over the surface of a wafer, the uniformity of the critical dimension of the linewidth decreases. As a result, it is difficult to adopt this method for actual production.

With respect to using an ArF laser, the hardness of the photosensitive material which us reactive to the ArF laser is low which results in distortion of the pattern.

In order to solve these problems, it is possible to use a hard mask. When using such a mask, however, an additional process is required for removing the hard mask after the etching process. Further, residuals of the hard mask, which are not completely removed, obstruct the formation of the silicide layer.

### BRIEF DESCRIPTION OF THE DRAWINGS

FIGS. 1 to 3 are cross-sectional views illustrating an example method for fabricating a semiconductor device performed in accordance with the teachings of the present invention.

### DETAILED DESCRIPTION

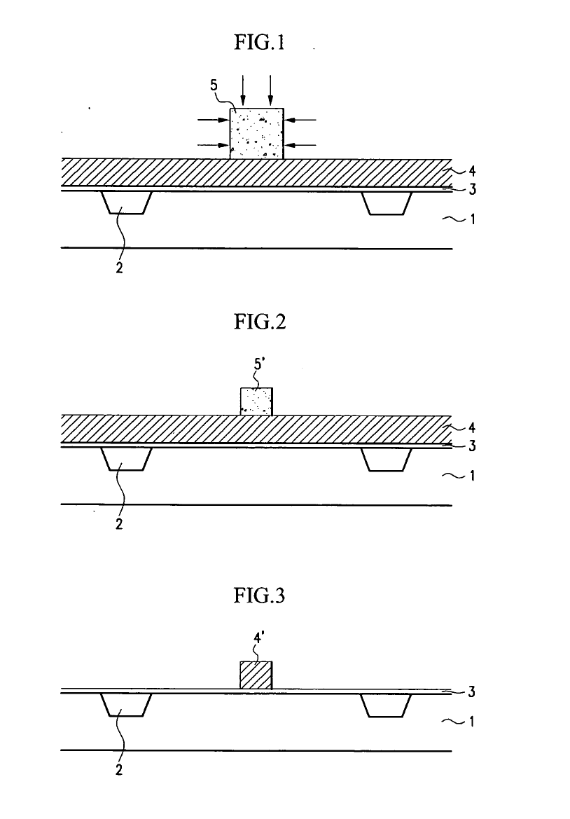

As shown in FIG. 1a, trenches 2 are formed in predetermined regions of a semiconductor substrate 1. An active area is defined between the trenches 2. The trenches 2 are defined as field areas and are pasted with dielectric material.

Next, a gate oxide layer 3 is formed on the semiconductor substrate 1. A polycrystalline silicon layer 4 is then deposited on the gate oxide layer 3 for forming a gate.

Next, a photoresist pattern 5 is formed by depositing a photosensitive film on the polycrystalline silicon layer 4, and then exposing and developing the photosensitive film while a reticle is aligned on the photosensitive film. The photoresist pattern 5 is preferably formed to have a thickness in the range of about 5000-6000 Å. If a KrF laser is used as the light source in the exposure process, the critical dimension of the photoresist pattern 5 is 0.15 μm.

The photoresist pattern 5 is then etched so as to reduce its linewidth. In particular, the photoresist pattern 5 is preferably isotropic etched by chemical dry etching (CDE) equipment. That is, the photoresist pattern, which is initially formed to have a thickness in about the 5000-6000 Å range, is processed by etching the photoresist pattern at a normal temperature (e.g., room temperature) in the CDE chamber into which gas including O₂ is injected so that the thickness of the photoresist pattern is reduced into a range of about 3000-4000 Å.

More specifically, the photoresist pattern is processed in a CDE chamber containing a gaseous environment including O₂ of about 10-20 sccm, CF₄ of about 40-60 sccm, and Ar of about 100-200 sccm, under pressure in the range of about 20-40 Pa, with a temperature in the range of about 20-30° C. and electric power in the range of about 200-400 W.

In this manner, only the photoresist pattern 5 is isotropic etched because the carbon combination of the photoresist pattern is broken without etching the polycrystalline silicon layer 4. As a result, the critical dimension of the etched photoresist pattern 5′ becomes narrower than 0.13 μm as shown in FIG. 2. In the illustrated example, the photoresist pattern 5′ is contracted in the same dimension throughout the entire wafer, thereby resulting in superior uniformity of the linewidth of the pattern.

Next, as shown in FIG. 3, while using the photoresist pattern, (whose linewidth is narrowed by etching), as a mask, the exposed portions of the polycrystalline silicon layer 4 are etched so as to form a gate 4′ having a predetermined width.

The etching process of the polycrystalline silicon layer 4 can be carried out in the chamber used for etching the photoresist pattern 5, with only changes of the etching conditions. Performing the etching processes for the photoresist pattern 5 and the polycrystalline silicon layer 4 in the same chamber simplifies the fabrication process.

After removing residuals of the photoresist pattern, the typical process for forming the MOS transistor is performed.

In the above example, an example process for forming a gate pattern is discussed. However, persons of ordinary skill in the art will readily appreciate that the disclosed fabrication process is not limited to forming a gate pattern, but, instead, can be adapted for forming other patterns.

As described above, since the photoresist pattern is etched by an isotropic etching technique using CDE equipment, it is possible to achieve a photoresist pattern having much finer linewidth then was possible in prior art techniques without replacing the light source. The disclosed methods achieve uniformly fine linewidths narrower than 0.13 μm while using a KrF laser as the photolithography light source. Thus, a linewidth narrower than 0.13 μm can be achieved in a simple and cost effective manner.

In view of the foregoing, persons of ordinary skill in the art will appreciate that photolithography techniques have been disclosed for fabricating a semiconductor device having a fine linewidth which cannot be achieved with prior art techniques using an identical light source. Further, the disclosed methods achieve a linewidth narrower than 0.13 μm without obstructing subsequent processes.

To this end, the example process described above isotropically etches the photoresist pattern using chemical dry etching (CDE) under specific conditions. That is, the illustrated method for fabrication a semiconductor device comprises: forming a film on a semiconductor substrate; forming a photoresist pattern on the film; etching the photoresist pattern by chemical dry etching (CDE) to make a width of the photoresist pattern narrower; etching the exposed film while using the photoresist pattern as a mask.

The photoresist pattern is preferably isotropic etched in a CDE chamber containing gas including O₂. The photoresist pattern is preferably formed at a thickness in a range of about 5000-6000 Å and then processed such that the thickness is reduced to a range of about 3000-4000 Å.

In more detail, the photoresist pattern is preferably processed in the CDE chamber into which O₂ of about 10-20 sccm, CF₄ of about 40-60 sccm, and Ar of about 100-200 sccm is injected to maintain a gaseous environment under pressure in a range of about 20-40 Pa at a temperature in a range of about 20-30° C. using electric power in a range of about 200-400 W.

Preferably, forming the photoresist pattern includes: coating a photoresist on the film; and forming the photoresist pattern by exposing and developing the photoresist while a reticle is positioned on the photoresist.

Etching the film can be performed in the same chamber used for the CDE.

This application claims priority to and the benefit of Korean Patent Application No. 10-2003-0066374, which was filed in the Korean Intellectual Property Office on Sep. 24, 2003. Korean Patent Application No. 10-2003-0066374 is incorporated herein by reference in its entirety.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

1. A method for fabricating a semiconductor device comprising:
forming a film on a semiconductor substrate;
forming a photoresist pattern on the film;
etching the photoresist pattern by chemical dry etching (CDE) to reduce a width of the photoresist pattern; and
etching an exposed portion of the film using the photoresist pattern as a mask.

2. A method as defined in claim 1 further comprising depositing an anti reflection coating on the film, wherein forming the photoresist pattern comprises forming the photoresist pattern on the anti reflection coating.

3. A method as defined in claim 1, wherein the photoresist pattern is formed at a thickness of about 5000-6000 Å, and etching the photoresist pattern by chemical dry etching reduces the thickness of the photoresist pattern to about 3000-4000 Å.

4. A method as defined in claim 1, wherein etching the photoresist pattern by chemical dry etching comprises isotropically etching the photoresist pattern in a chamber into which a gas including O₂ is injected.

5. A method as defined in claim 1, wherein the CDE is performed in a chamber contained O₂, CF₄, and Ar.

6. A method as defined in claim 4, wherein the gas includes O₂, CF₄, and Ar.

7. A method as defined in claim 5, wherein the O₂ is injected at about 10-20 sccm, the CF₄ is injected at about 40-60 sccm, and the Ar is injected at about 100-200 sccm.

8. A method as defined in claim 6, wherein the O₂ is injected at about 10-20 sccm, the CF₄ is injected at about 40-60 sccm, and the Ar is injected at about 100-200 sccm.

9. A method as defined in claim 1, wherein the CDE is performed under a pressure of about 20-40 Pa, at a temperature of about 20-30° C., and by applying electric power of about 200-400 W.

10. A method as defined in claim 7, wherein the CDE is performed under a pressure of about 20-40 Pa, at a temperature of about 20-30° C., and by applying electric power of about 200-400 W.

11. A method as defined in claim 1, wherein forming the photoresist pattern comprises:
coating a photoresist on the film;
positioning a reticle on the photoresist; and
developing exposed portions of the photoresist.

12. A method as defined in claim 1, wherein the photoresist pattern is formed with a KrF light source to form a photoresist pattern having a first width.

13. A method as defined in claim 1, wherein etching the exposed portion of the film is performed in a same chamber used for the CDE.

14. A method as defined in claim 1, wherein the film is formed of a polycrystalline silicon.

15. A method as defined in claim 1, further comprising forming a gate oxide layer on the semiconductor substrate before forming the film such that the film is formed on the gate oxide layer.
